(19) United States
(12) Patent Application Publication
(10) Pub. No.: US 2026/0082953 A1
(43) Pub. Date: Mar. 19, 2026

(54) INTERCONNECTS FOR COMPLEMENTARY FIELD-EFFECT TRANSISTOR (CFET) DEVICES

(71) Applicant: Intel Corporation, Santa Clara, CA (US)

(72) Inventors: Alessandro Uber, Muenchen (DE); Joachim Assenmacher, Unterhaching (DE)

(21) Appl. No.: 18/889,150

(22) Filed: Sep. 18, 2024

(51) Int. Cl. H01L 23/538; H01L 21/822; H01L 27/06; H01L 27/092

(52) U.S. Cl. CPC H10W 70/65; H10D 84/038; H10D 84/856; H10D 88/00; H10D 88/01; H10W 70/611; H10W 70/635

(57) ABSTRACT

Embodiments herein relate to interconnects in Complementary Field-Effect Transistor (CFET) devices. In one aspect, an epitaxial silicon material is used to provide a conductive path which extends laterally between first and second CFET devices. In one example, the conductive path extends between drains of n-channel and p-channel Field-Effect Transistors (FETs) of the CFETs. In another example, the conductive path extends between gates of the n-channel and p-channel FETs of the CFETs. Each CFET may be provided in area allocated to a standard cell. In another aspect, an area of a standard cell allocated to passive devices is used for a through-silicon via which extends from a front side metal layer to a back side metal layer.

### BACKGROUND

Computing devices rely on transistors to perform their intended functions. Performance, power consumption and size are important goals. A Complementary Field-Effect Transistor (CFET) device is one example of a device that has been developed to meet these goals. A CFET device has a stack comprising one transistor above another. For example, a CFET device can include an n-channel metal-oxide-semiconductor field-effect transistor (MOSFET) positioned above a p-channel MOSFET. More generally, multiple n-channel MOSFETs can be provided in an upper region of a stack while multiple p-channel MOSFETs can be provided in a lower region of the stack. However, various challenges are encountered in providing interconnects in such devices.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 depicts a cross-sectional view of an example semiconductor device 100 having front side and back side metal layers, according to various embodiments.

FIG. 2 depicts a cross-sectional view of a CFET device 200 in an y-z plane, including an n-channel MOSFET TN above a p-channel MOSFET TP, where interconnects to the device are from top side metal layers, according to various embodiments.

FIG. 3 depicts a cross-sectional view of the CFET device 200 of FIG. 2 in an x-z plane along the dashed line 201, according to various embodiments.

FIG. 4 depicts a cross-sectional view of a CFET device 400 corresponding to the CFET device 200 of FIG. 2, where interconnects to the n-channel MOSFET TN are from top side metal layers and interconnects to the p-channel MOSFET TP are from bottom side metal layers, according to various embodiments.

FIG. 5 depicts a cross-sectional view of a CFET device 500 corresponding to the CFET device 400 of FIG. 4, where direct interconnects are also provided between the n-channel MOSFET TN and the p-channel MOSFET TP, according to various embodiments.

FIG. 6 depicts an example circuit diagram of an inverter 600 which can be implemented using CFET devices described herein, according to various embodiments.

FIG. 7 depicts a cross-sectional view of a CFET device 700 corresponding to the CFET device 200 of FIG. 2, and configured consistent with the inverter 600 of FIG. 6, where a conductive panel 701 extends between the drain TND of the n-channel MOSFET TN and the drain TPD of the p-channel MOSFET TP, according to various embodiments.

FIG. 8 depicts a cross-sectional view of a CFET device 800 corresponding to the CFET device 200 of FIG. 2, and configured consistent with the inverter 600 of FIG. 6, where a conductive path 801 of epitaxial silicon is provided from the drain TND of the n-channel MOSFET TN to the drain TPD of the p-channel MOSFET TP, according to various embodiments.

FIG. 9A depicts a cross-sectional view of a CFET structure 900A which includes CFET devices 920A and 950A, configured consistent with the inverter 600 of FIG. 6, where a conductive path 901A of epitaxial silicon extends between the CFET devices to provide a conductive path within each CFET device and between the CFET devices, according to various embodiments.

FIG. 9B depicts a cross-sectional view of a CFET structure 900B similar to the structure 900A of FIG. 9A, where a conductive path 901B of epitaxial silicon extends between the gates G and G2 of CFET devices 920B and 950B, respectively, according to various embodiments.

FIG. 9C depicts a cross-sectional view of a CFET structure 900C similar to the structure 900A of FIG. 9A, where a conductive path 901C of epitaxial silicon extends between gates TNG and TPG of a first CFET device 920C and gates TN2G and TP2G of a second CFET device 950C, according to various embodiments.

FIG. 10 depicts a perspective view of the conductive path 901A of FIG. 9A, according to various embodiments.

FIG. 11 depicts a view in the x-y plane of another example conductive path 1100 of epitaxial silicon, according to various embodiments.

FIG. 12 depicts a perspective view of the conductive path 1100 of FIG. 10, according to various embodiments.

FIG. 13 depicts an example circuit diagram of a multiplexer 1300 which can be implemented using CFET devices as described herein, according to various embodiments.

FIG. 14 depicts an example standard cell 1400 with a conventional layout of contacts 1401-1404, where the standard cell can be implemented using CFET devices as described herein, according to various embodiments.

FIG. 15 depicts an example standard cell 1500 with a relative placement (RP) layout of contacts 1501-1504, where the standard cell can be implemented using CFET devices as described herein, according to various embodiments.

FIG. 16 depicts an example layout of a group 1600 of standard cells having a conventional layout of contacts consistent with FIG. 14, and metal layers which provide conductive paths between the contacts, according to various embodiments.

FIG. 17 depicts an example layout of a group 1700 of standard cells having an RP layout of contacts consistent with FIG. 15, and metal layers which provide conductive paths between the contacts, according to various embodiments.

FIG. 18 depicts an example layout of a group 1800 of standard cells, where straight and L-shaped conductive paths 1801 and 1802, respectively, of epitaxial silicon extend between contacts of standard cells, according to various embodiments.

FIG. 19 depicts an example layout of a group 1800A of standard cells corresponding to the group 1800 of FIG. 18, where conductive paths of epitaxial silicon and a channel provide overlapping first and second conductive paths 1910 and 1920, respectively, according to various embodiments.

FIG. 20 depicts an example end view of the conductive paths of epitaxial silicon and the channel of FIG. 19 in the y-z plane, according to various embodiments.

FIG. 21 depicts an example layout of a group 2100 of standard cells including clock standard cells (CSCs), data standard cells (DSCs) and decoupling capacitors (cap.), according to various embodiments.

FIG. 22 depicts an example layout of a group 2200 of standard cells, where a through-silicon via (TSV) 2210 is placed in the area 2205 outside the cells, according to various embodiments.

FIG. 23 depicts an example clock standard cell (CSC) which includes an active portion 2310 and passive portions 2320 and 2330, where the passive portion 2320 includes areas 2322 and 2324 for decoupling capacitors (cap.) and the passive portion 2330 includes areas 2332 and 2334 for decoupling capacitors, according to various embodiments.

FIG. 24 depicts an example clock standard cell (CSC) 2400 which includes an active portion 2410 and vias 2421 and 2431 located in the passive portions 2420 and 2430, respectively, according to various embodiments.

FIG. 25 depicts an example layout 2500 of the clock standard cell 2400 of FIG. 24 with another clock standard cell 2510 and data standard cells 2550 and 2570, according to various embodiments.

FIG. 26 illustrates an example of components that may be present in a computing system 2650 for implementing the techniques (e.g., operations, processes, methods, and methodologies) described herein.

### DETAILED DESCRIPTION

As mentioned at the outset, various challenges are encountered in providing interconnects in CFET devices.

The design of a CFET device can involve standard cells. In integrated circuit (IC) design, a standard cell refers, e.g., to a pre-designed, reusable building block used to construct complex digital circuits. Standard cells are important components in the design of digital ICs, particularly in application-specific integrated circuits (ASICs) and custom microprocessors. A standard cell is typically rectangular in shape, having a fixed height and variable width, so that multiple standard cells can be placed in uniform rows to facilitate the circuit layout process. Additional, a clock standard cell (CSC) is used in a clock path while a data standard cell (DSC) is used in a data path. A standard cell typically includes an area allocated for active components such as inverters, buffers, and integrated clock gates and areas allocated for passive components such as decoupling capacitors. Example of active components include logic gates such as AND, OR, NAND and NOR gates, storage elements such as flip-flops and latches, arithmetic components such as adders and multipliers, and other functions such as multiplexers, buffers, and inverters.

Standard cells have a number of contacts, also referred to as pins or nodes, which are used to provide input or outputs to other standard cells and/or to receive power or connect to ground. In some cases, the pins are arranged at fixed locations such as at the corners and the center of the standard cell. In another case referred to as relative placement (RP), the pins can be provided at locations which facilitate the placement of interconnects to reduce the gap between cells and reduce routing length.

While CFET devices save space on a substrate due to the vertical arrangement of transistors, it is challenging to provide interconnects to the source, drain and gate of the transistors. In some cases, front side and back side metal layers are used to provide such interconnects. However, these interconnects provide additional process complexities and consume space. Moreover, the goal of reducing the size of the CFET device causes a reduction in the available routing tracks in the first metal layer of the front side, for instance.

The solutions provided herein address the above and other challenges. In one aspect, a semiconductor device is provided having a lateral conductive path within and between CFET devices. The conductive path can comprise doped epitaxial silicon, for instance, which has good conductivity and is compatible with the overall fabrication process. The epitaxial silicon path can remove the need for some conductive paths in the front side and/or back side metal layers and their associated vias.

A standard cell architecture can be used which leverages CFET technology to allow a direct connection between different CFET devices, and/or within a CFET device, with an epitaxial silicon path. All or part of the side of the rectangular standard cell can be reserved to provide an output pin in an epitaxial layer and all or part of the opposite side of the rectangular standard cell can be used to provide one or more input pins in the epitaxial layer.

Advantages include increasing the number of standard cells (stdcells), which can effectively reduce either the inter-cell gap or routing between cells of the same group. The usage of routing resources above the group is also reduced. Overall, this translates into reduced power consumption and reduced area for the design. Another advantage is the absence of any connection of such pins/vias to the front and/or back side metal layers. This reduces capacitance and thus power consumption. Another advantage is reduced coupling capacitance to other nets of the design, which translates into improved performance.

Another challenge is that the placement of through-silicon vias (TSVs) causes additional constraints in the placement of standard cells on a substrate. TSVs can be used, e.g., to connect front side and back side metal layers. However, the TSVs can form a parasitic capacitance with the metal layers and the transistors which impacts the functionality or performance of the standard cells.

The solutions provided herein address the above and other challenges. In one aspect, an area reserved for passive components in a standard cell is used for a TSV. One or more TSVs can be associated with a standard cell. The solution can use CSCs or DSCs, but may be more advantageous in connection with CSCs which are more susceptible to interference.

For example, clock standard cells can be designed to include integrated decoupling capacitors (intdecap) and one or more TSVs to enable a front side-to-back side feedthrough connection for CFET technology. The TSVs can be optimally placed to avoid functional parts of the standard cell. One example of a TSV is the PowerVia by Intel Corp. A TSV can be made of metal and/or conductive silicon, for example.

Advantages include optimizing and reducing the area occupied by capacitors and TSVs. Another advantage is that a large number of TSVs can be made available for use opportunistically at different steps of the implementation flow. In this way, the placement of already existing standard cells does not need to be changed. Another advantage is that the presence of neighboring TSVs can be removed from the boundary conditions used to characterize the clock standard cells, thus allowing improvements in the modelled performance.

These and other features will be further apparent in view of the following discussion.

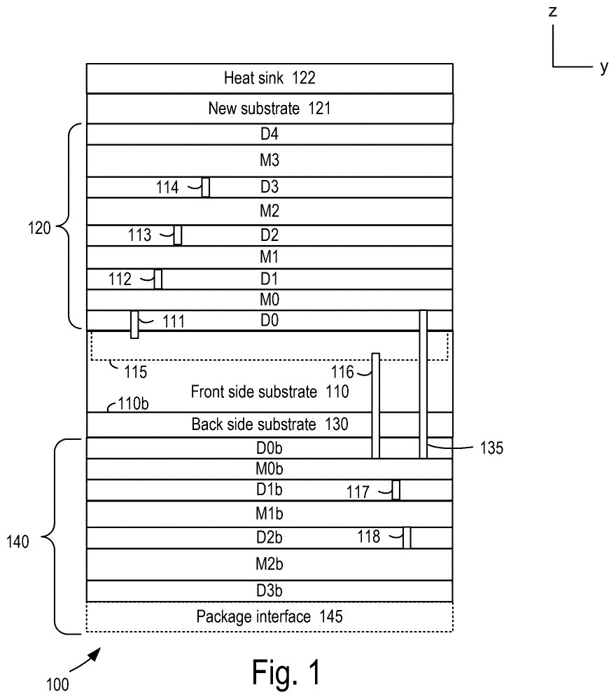

FIG. 1 depicts a cross-sectional view of an example semiconductor device 100 having front side and back side metal layers, according to various embodiments. The cross-section is in a y-z plane, where z represents height. In one approach, a front side substrate 110 with a transistor layer 115 is prepared, and a front side stack 120 of alternating dielectric and metal layers is fabricated on top of the front side substrate. This simplified example includes five dielectric layers D0-D4 and four front side metal layers M0-M3. The transistor layer 115 can include CFET devices and epitaxial interconnects as described herein. A new substrate 121 and a heat sink 122 are provided on top of the front side stack 120, and the resulting structure is inverted. The new substrate may comprise a dielectric and is an interface to the heat sink.

The backside substrate 130 can be prepared separately with structures to connect circuits in the transistor layer 115 to the backside stack 140. The backside substrate 130 is then inverted and thinned, and attached to the backside 110b of the front side substrate. The backside stack includes alternating dielectric and metal layers, such as dielectric layers D0b-D3b and metal layers M0b-M2b. A package interface 145 is also provided adjacent to the bottom side stack, for attachment to a package. The resulting structure is then inverted to obtain the structure shown.

Example vias 111-114 are depicted in the front side stack to connect the transistor layer 115 and front side metal layers, and example vias 116, 117 and 118 are depicted in the back side stack to connect the transistor layer 115 and metal layers in the back side stack. Another example via 135 is a TSV which connects a front side metal layer, e.g., M0, to a back side metal layer, e.g., M0b. Vias can connect adjacent or non-adjacent metal layers. The metal layers include tracks that extend laterally in the x and y directions. The vias can connect to specific contact points such as to gates, drain and sources of transistors in the transistor layer, and to power and ground. In one approach, the top side metal layers are used for routing data and clock signals and the back side metal layers are used to provide power and ground paths.

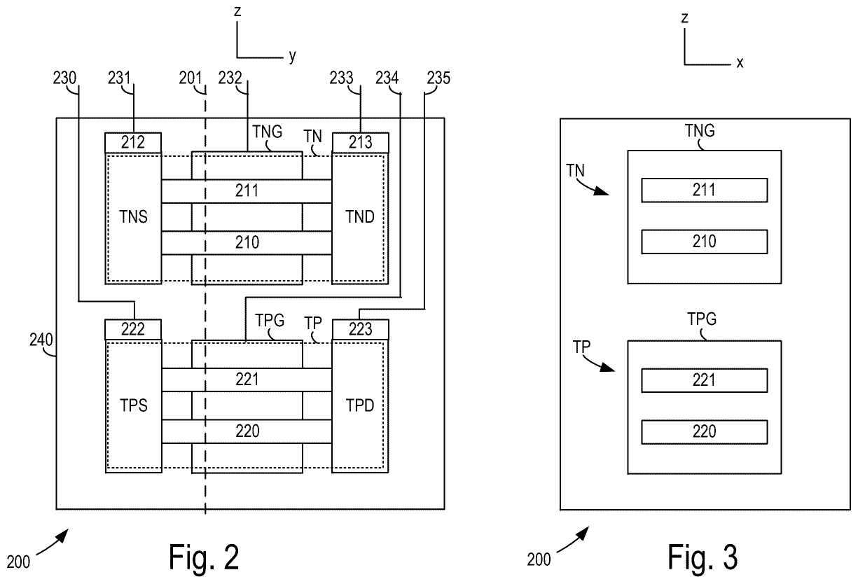

FIG. 2 depicts a cross-sectional view of a CFET device 200 in an y-z plane, including an n-channel MOSFET (nMOS) TN above a p-channel MOSFET (pMOS) TP, where interconnects to the device are from top side metal layers, according to various embodiments. Alternatively, the positions of the transistors can be reversed. The nMOS TN includes a source TNS, a drain TND, a gate TNG and one or more ribbons 210 and 211 of p-type silicon which extend from the source to the drain. The source, drain and gate of a transistor are terminals of a transistor. The gate TNG extends all around the ribbons, which can form respective conductive channels from the source to the drain when the control gate voltage is sufficiently high. The pMOS TP includes a source TPS, a drain TPD, a gate TPG and one or more ribbons 220 and 221 of n-type silicon which extend from the source to the drain. The gate TPG extends all around the ribbons, which can form respective conductive channels from the source to the drain when the control gate voltage is sufficiently low.

The gate material can be, e.g., any known metal gate material, such as TiN, TiAl, or TiC. The ribbons can be, e.g., nanosheet channels which are made up of thin, alternating layers of silicon and silicon germanium. The source and drain terminals can be doped silicon including epitaxial silicon.

The CFET includes conductive paths, e.g., interconnects, which extend upward from the terminals to the top metal layer for routing. In one approach, the vertical portions of the paths (z-direction) are vias such as metal plated through-vias, for example, or other conductive material. The horizontal (y-direction) portions of the paths can be a conductive silicon, for instance such as polysilicon. The conductive paths can be coupled to contacts of the source and drain terminals. For example, the conductive paths 230, 231, 233 and 235 are coupled to contacts 222, 212, 213 and 223, respectively of TPS, TNS, TND and TPD, respectively. The conductive paths 232 and 234 can be coupled directly to TNG and TPG, respectively, in one approach. The transistors TN and TP can be embedded in a dielectric material 240.

FIG. 3 depicts a cross-sectional view of the CFET device 200 of FIG. 2 in an x-z plane along the dashed line 201, according to various embodiments. This view shows the ribbons 210 and 211 of TN and the ribbons 220 and 221 of TP.

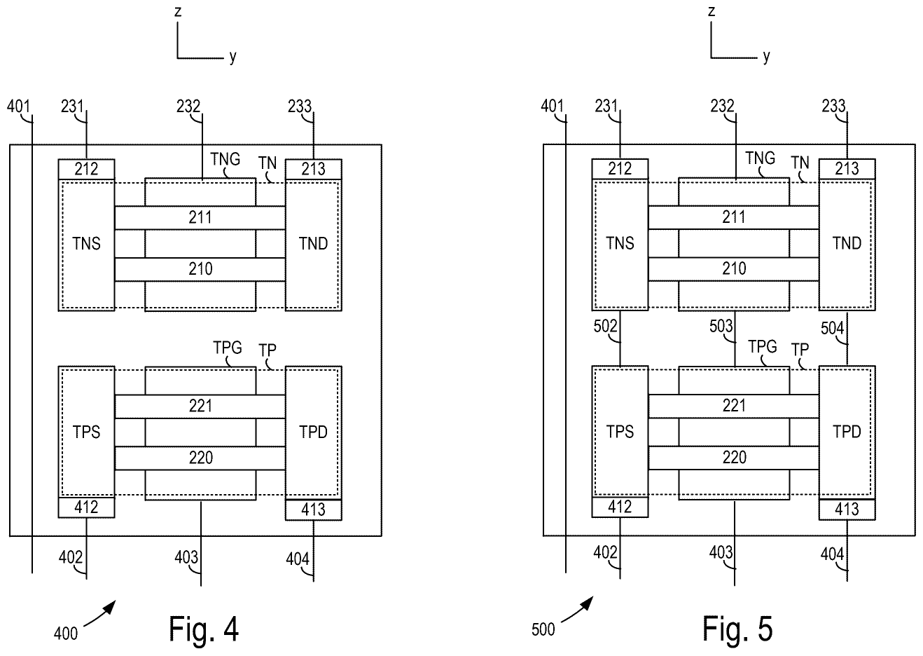

FIG. 4 depicts a cross-sectional view of a CFET device 400 corresponding to the CFET device 200 of FIG. 2, where interconnects to the n-channel MOSFET TN are from top side metal layers and interconnects to the p-channel MOSFET TP are from bottom side metal layers, according to various embodiments. The top side conductive paths 231-233 discussed above are repeated. A conductive path 401 represents a TSV such as the TSV 135 of FIG. 1. Additionally, at the bottom, the conductive paths 402 and 404 are coupled to contacts 412 and 413, respectively of TPS and TPD, respectively. The contact 403 is coupled directly to TPG.

FIG. 5 depicts a cross-sectional view of a CFET device 500 corresponding to the CFET device 400 of FIG. 4, where direct interconnects are also provided between the n-channel MOSFET TN and the p-channel MOSFET TP, according to various embodiments. This example adds one or more of conductive paths 502, 503 and 504, depending on the desired functionality. The conductive paths 502, 503 and 504 extends from TNS to TPS, TNG to TPG, and TND to TPD, respectively. These conductive paths can be provided by a non-metal such as doped silicon.

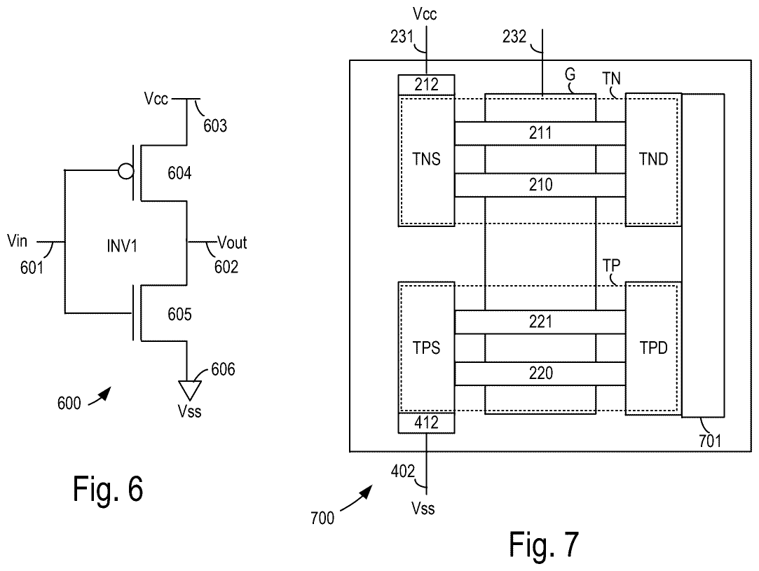

FIG. 6 depicts an example circuit diagram of an inverter 600, according to various embodiments. The transistors in a CFET device and the associated interconnects can be configured to provide different types of circuits including those mentioned previously in connection with a standard cell. The inverter 600 is merely one example among many possible examples. The inverter provides a simple example as it involves only two transistors. Other types of CFET devices can include more than two transistors. For example, six- or eight-transistor CFET devices can be used to provide a static random-access memory (SRAM) cell.

The inverter includes an input node 601 which receives a voltage Vin and an output node 602 which provides a voltage Vout, which is the inverse of Vin. The output node is in a series path which includes a power supply node 603 at Vcc, a pMOS transistor 604, the output node 602, an nMOS transistor 605, and a ground node 606 at a voltage Vss such as 0 V. These transistors have their gates coupled to each other and to the input node 601. A drain of the transistors 604 and a drain of the transistor 605 are coupled to each other and to the output node 602. A source of the transistor 604 is coupled to the power supply node 603, and a source of the transistor 605 is coupled to the ground node 606.

When Vin is high, the transistor 604 turns off (non-conductive) and the transistor 605 turns on (conductive), coupling Vout to Vss or a logical 0. When Vin is low (=0 V), the transistor 604 turns on and the transistor 605 turns off, coupling Vout to Vcc or a logical 1.

FIG. 7 depicts a cross-sectional view of a CFET device 700 corresponding to the CFET device 200 of FIG. 2, and configured consistent with the inverter 600 of FIG. 6, where a conductive panel 701 extends between the drain TND of the n-channel MOSFET TN and the drain TPD of the p-channel MOSFET TP, according to various embodiments. To configure the CFET device as an inverter, a conductive panel 701, e.g., comprising conductive silicon, is added to provide a conductive path between the drain TND of TN and the drain TPD of TP. The conductive panel 701 corresponds to the output node 602 of FIG. 6. Additionally, a single gate G, controlled by a voltage on the conductive path 232, is provided which extends around the ribbons of both TN and TP. This corresponds to the input node 601 of FIG. 6. The conductive paths 231 and 402 provide Vcc and Vss, respectively, to TNS and TPS, respectively.

Alternatively, a conductive path is coupled to the bottom of the gate G to a back side metal layer.

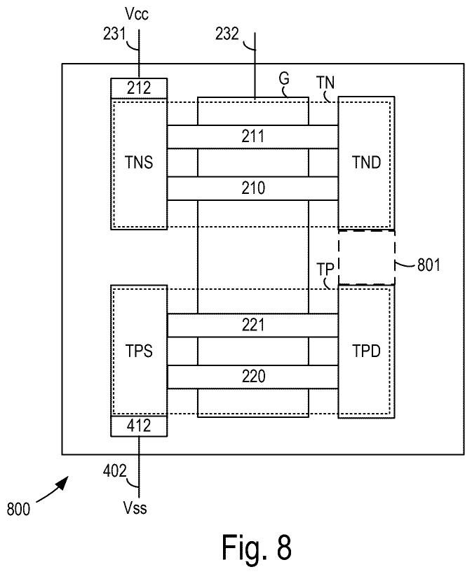

FIG. 8 depicts a cross-sectional view of a CFET device 800 corresponding to the CFET device 200 of FIG. 2, and configured consistent with the inverter 600 of FIG. 6, where a conductive path 801 of epitaxial silicon is provided from the drain TND of the n-channel MOSFET TN to the drain TPD of the p-channel MOSFET TP, according to various embodiments. The conductive path 801 extends from a bottom surface of TND to a top surface of TPD. This allows the drains of TN and TP to be coupled without adding the conductive panel 701.

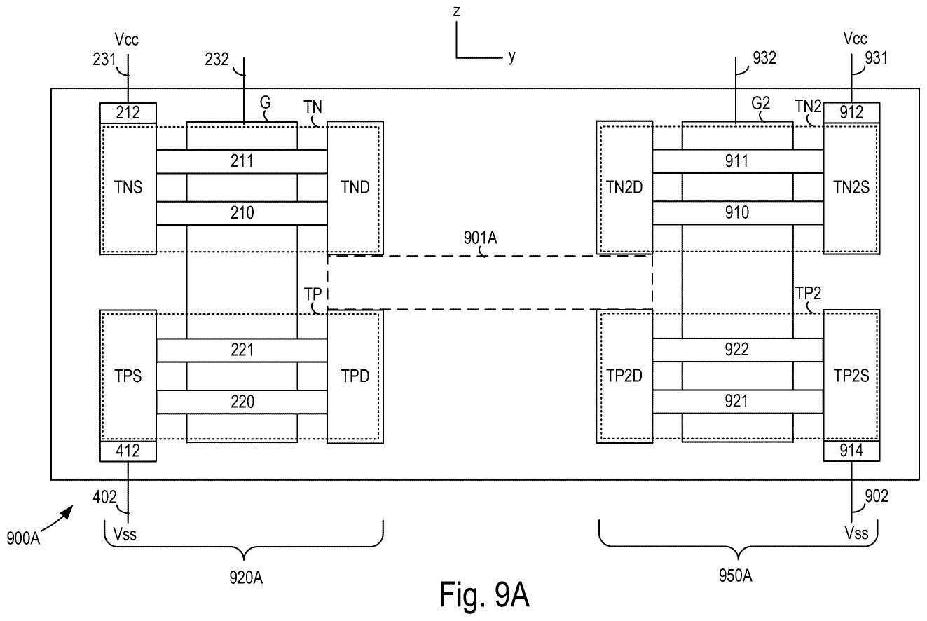

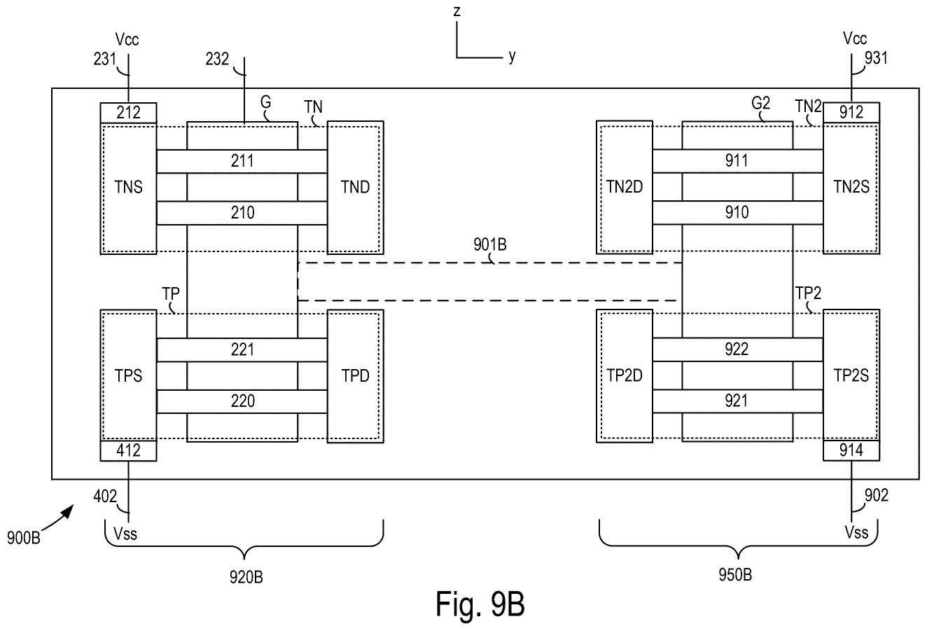

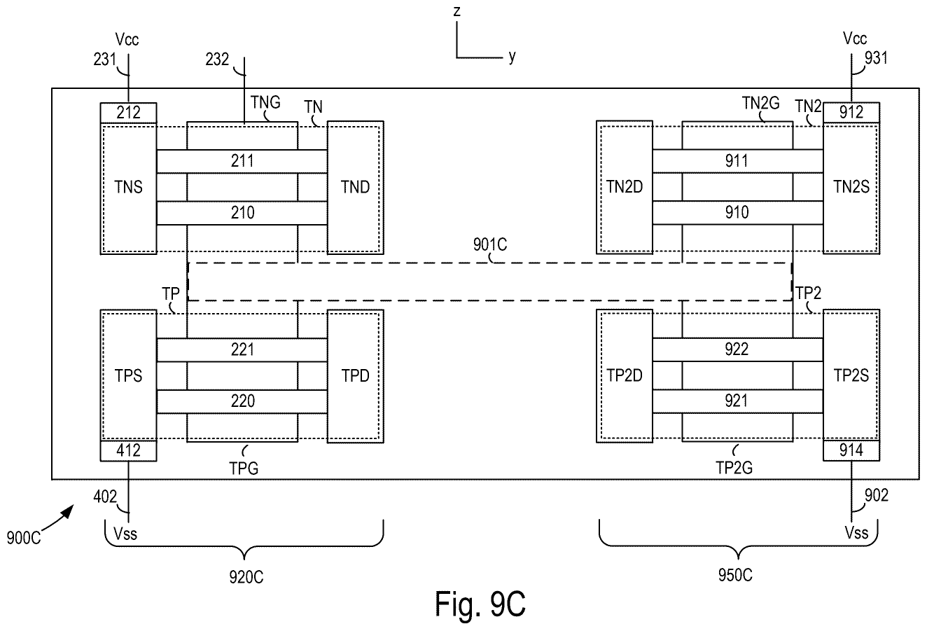

FIG. 9A depicts a cross-sectional view of a CFET structure 900A which includes CFET devices 920A and 950A, configured consistent with the inverter 600 of FIG. 6, where a conductive path 901A of epitaxial silicon extends between the CFET devices to provide a conductive path within each CFET device and between the CFET devices, according to various embodiments. The second CFET device 950A is a mirror image of the first CFET device 920A. The second CFET device 950A includes an nMOS transistor TN2 above a pMOS transistor TP2. TN2 includes a source TN2S, a drain TN2D, and ribbons 910 and 911. A contact 912 of TN2S is coupled to a conductive path 931 at Vcc. A contact 914 of TP2S is coupled to a conductive path 902 at Vss. TP2 includes a source TP2S, a drain TP2D, and ribbons 921 and 922. TN2 and TP2 have a common gate G.

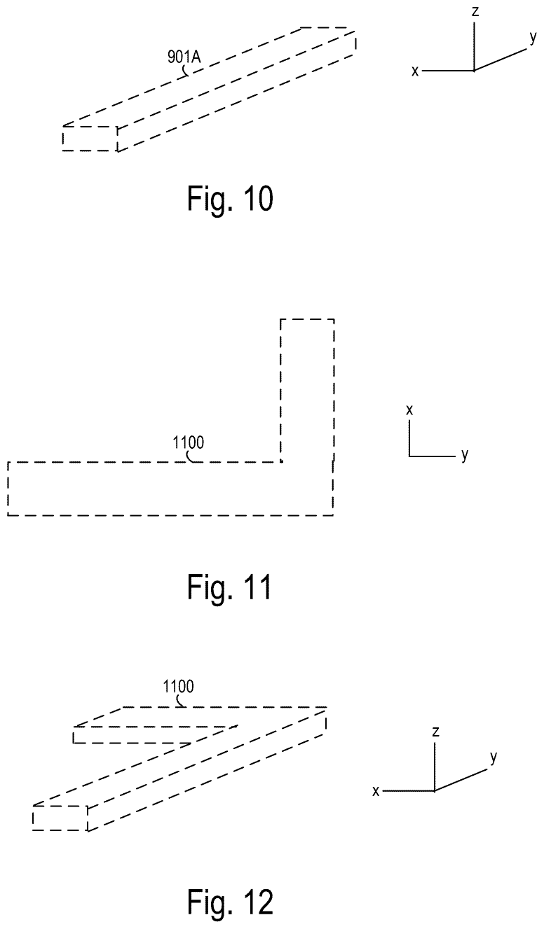

The conductive path 901A (e.g., a conductive epitaxial silicon material) extends laterally, e.g. parallel to a plane of the substrate in the y-direction, in a straight path in this example. See also FIG. 10. The conductive path could also extend laterally in the x- and y-directions, taking one or more right angle turns, for instance. See also FIGS. 11 and 12.

The conductive path 901A is within, e.g., internal to, the first CFET device, between TND and TPD, and within the second CFET device, between TN2D and TP2D. The conductive path 901A further extends between the first and second CFET devices, that is, from between TND and TPD, to between TN2D and TP2D. This example results in two inverters which have their outputs coupled by the conductive path 901A. This is merely one example of many possible examples of how one or more lateral conductive paths can extend between different points of different transistors, e.g., sources, drains and gates. For example, a conductive path can be used to connect the source/drain of any FET to the gate of any other FET. More generally, a conductive path can be used to connect the source, drain and/or gate in a CFET to the source, drain and/or gate in one or more other CFETs.

The conductive path 901A can be formed of doped epitaxial silicon using various fabrication processes. Non-epitaxial silicon could also be used. A layer of epitaxial silicon can be formed at the top of a substrate and processed through fabrication techniques such as etching to obtain the desired pattern. In one approach, a lower layer of the CFET structure such as TPS, TPD, TP2D and TP2S is formed first, followed by the conductive path 901A in a middle layer of the CFET structure, followed by TNS, TND, TN2D and TN2S in an upper layer of the CFET structure.

FIG. 9B depicts a cross-sectional view of a CFET structure 900B similar to the structure 900A of FIG. 9A, where a conductive path 901B of epitaxial silicon extends between the gates G and G2 of CFET devices 920B and 950B, respectively, according to various embodiments. As mentioned, various types of connections can be made between the sources, drains and gates. In this case, the connection is between the gates. Many other options are possible. Note that the conductive path 932 in FIG. 9A can advantageously be removed since the gates G and G2 are both controlled by a voltage on the conductive path 232.

FIG. 9C depicts a cross-sectional view of a CFET structure 900C similar to the structure 900A of FIG. 9A, where a conductive path 901C of epitaxial silicon extends between gates TNG and TPG of a first CFET device 920C and gates TN2G and TP2G of a second CFET device 950C, according to various embodiments. In this case, the conductive paths provides a conductive path between the gates of the transistors in each of the first and second CFETs, as well as a conductive paths between the gates of the first and second CFETs.

FIG. 10 depicts a perspective view of the conductive path 901A of FIG. 9A, according to various embodiments. The conductive paths extends in a straight path and may have a generally rectangular cross-section.

FIG. 11 depicts a view in the x-y plane of another example conductive path 1100 of epitaxial silicon, according to various embodiments. The conductive path 1100 extends in the y-direction and turns at a right angle to extend in the x-direction. The conductive path 1100 is L-shaped. A conductive path can have many other shapes. For example, a conductive path can have one or more steps in height, e.g., a step up and/or down, such as to cross over, while avoiding a short circuit with, another conductive path.

FIG. 12 depicts a perspective view of the conductive path 1100 of FIG. 10, according to various embodiments. The conductive paths extends in two straight paths which may each have a generally similar rectangular cross-section.

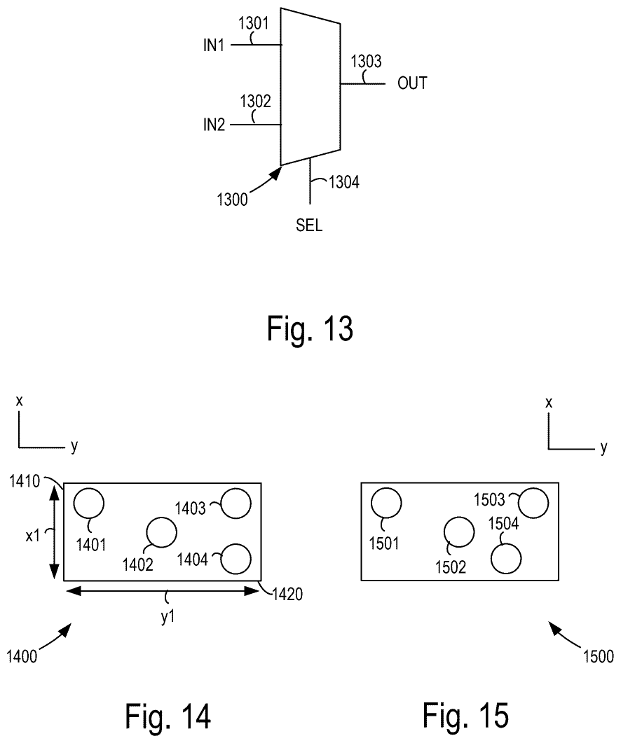

FIG. 13 depicts an example circuit diagram of a multiplexer 1300 which can be implemented using CFET devices as described herein, according to various embodiments. A multiplexer is provided merely as an example of one of many types of circuits which can be implemented. The multiplexer includes first and second data inputs 1301 and 1302, respectively, which receive voltages IN1 and IN2, respectively, and a control input 1304 which receives a selection signal SEL. Based on SEL, IN1 or IN2 is passed to the output 1303. The multiplexer thus includes four nodes (contacts, pins or connection points) which are to be connected to other circuits. The nodes can be connected to other locations by a via to a metal layer.

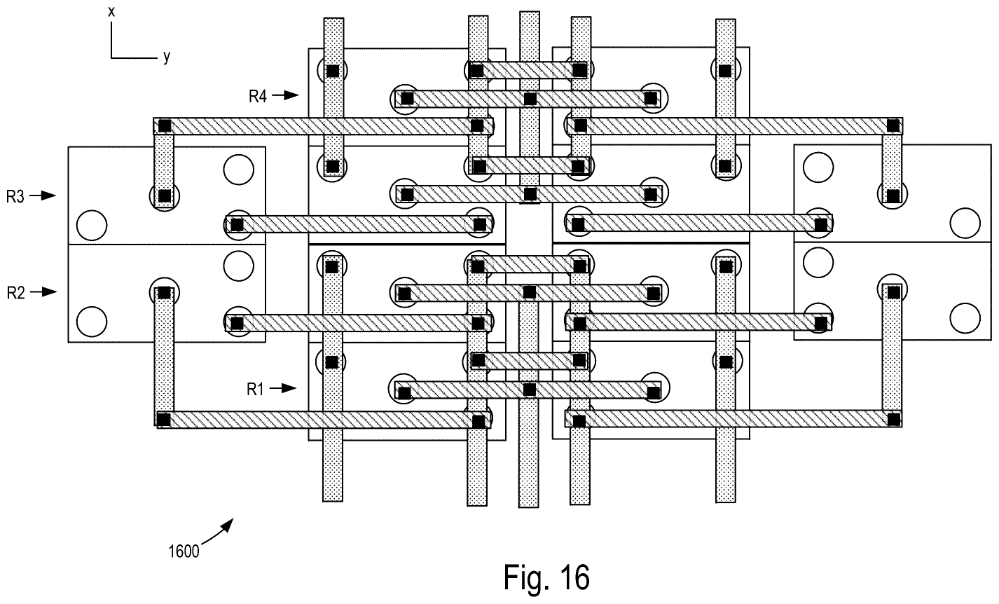

FIG. 14 depicts an example standard cell 1400 with a conventional layout of contacts 1401-1404, where the standard cell can be implemented using CFET devices as described herein, according to various embodiments. The standard cell has a height x1 on the cell's short side 1410 and a width y1 on the cell's long side 1420, assuming a rectangular shape. Each circle represents a node of the multiplexer. For example, the nodes 1401, 1402, 1403 and 1404 can represent IN1, IN2, SEL and OUT, respectively. The conventional standard cell layout results in the layout of FIG. 16, which is not optimized in size.

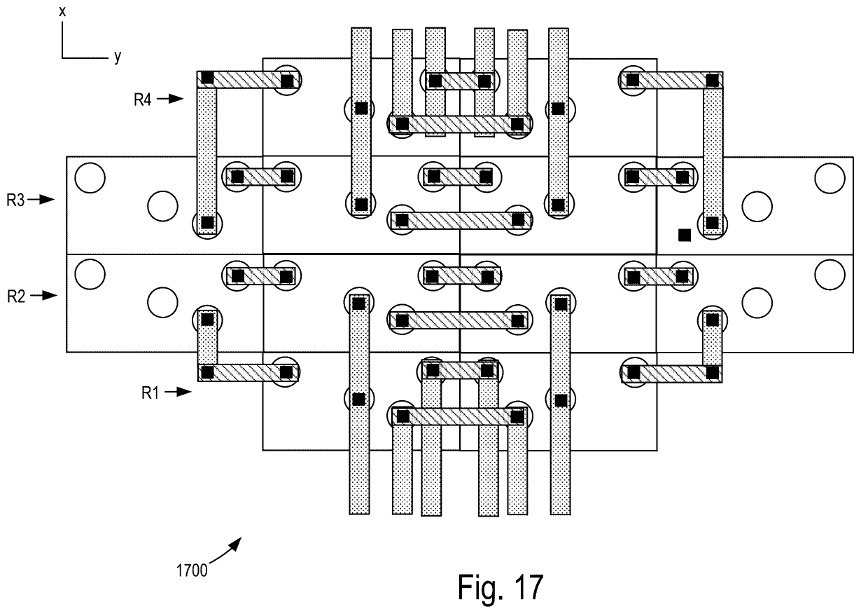

FIG. 15 depicts an example standard cell 1500 with a relative placement (RP) layout of contacts 1501-1504, where the standard cell can be implemented using CFET devices as described herein, according to various embodiments. As before, each circle represents a node of the multiplexer. For example, the nodes 1501, 1502, 1503 and 1504 can represent IN1, IN2, SEL and OUT, respectively. The RP standard cell layout results in the layout of FIG. 17, which is optimized in size since there is flexibility to move the nodes. For example, the position of the node 1504 is different than the position of the node 1404.

RP is a layout technique for semiconductor devices which is supported by some place and route tools. These tools provide a very predictable placement of standard cells while mingling these structures with standard cells which are placed without such constraints. Conventional standard cells can be used to design an RP structure. However a minimization of the space between the standard cells and of the wires connecting them often requires specially designed standard cells, which puts their input and output pins at locations which could make their connection more convenient.

FIG. 16 depicts an example layout of a group 1600 of standard cells having a conventional layout of contacts consistent with FIG. 14, and metal layers which provide conductive paths between the contacts, according to various embodiments. The metal layers run in tracks in the x- and y-directions. In this example, the tracks or routing paths in the x-direction have a dotted pattern and the tracks in the y-direction have a slanted line pattern. The x-direction tracks may represent a first metal layer such as M0 while the y-direction tracks may represent a second metal layer such as M1. The dark squares represent connection points of the tracks, e.g., to a contact of a standard cell and/or to another track.

The group of cells includes a first row R1 having two cells, a second row R2 having four cells, a third row R3 having four cells, and a fourth row R4 having two cells. There are significant gaps between cells in the y-direction due to the constraints imposed by the conventional layout. This results in longer routing paths.

FIG. 17 depicts an example layout of a group 1700 of standard cells having an RP layout of contacts consistent with FIG. 15, and metal layers which provide conductive paths between the contacts, according to various embodiments. As before, the group of cells includes a first row R1 having two cells, a second row R2 having four cells, a third row R3 having four cells, and a fourth row R4 having two cells. However, there are no gaps, or reduced gaps, between cells in the y-direction due to the flexibility provided by the RP layout. This reduces the lengths of the routing paths.

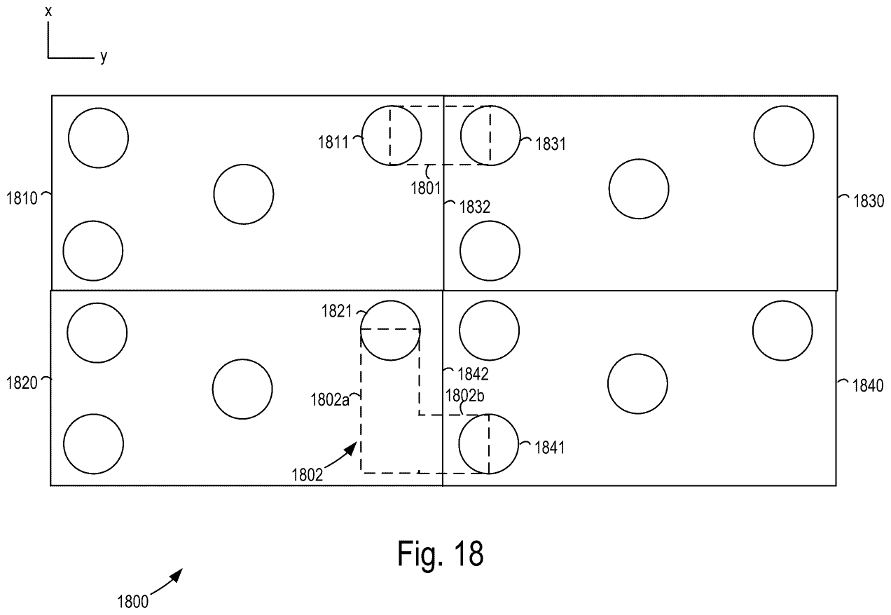

FIG. 18 depicts an example layout of a group 1800 of standard cells, where straight and L-shaped conductive paths 1801 and 1802, respectively, of epitaxial silicon extend between contacts of standard cells, according to various embodiments. The group include standard cells 1810, 1820, 1830 and 1840. The cells may be adjacent to one another along their short and long ends, e.g., abutting and sharing a common boundary. An example node 1811 in the standard cell 1810 is connected to an example node 1831 in the standard cell 1830 by the conductive path 1801, which extends across a boundary 1832 between the two cells 1810 and 1830.

Also, an example node 1821 in the standard cell 1820 is connected to an example node 1841 in the standard cell 1840 by the conductive path 1802. This conductive path includes a first portion 1802a which extends in the x-direction in the cell 1820, and a second portion 1802b which extends to the node 1841, across a boundary 1842 between the two cells 1820 and 1840.

Optionally, the conductive path can extend between cells which are non-adjacent. Although, generally, a shorter distance is more practical. Also, a conductive path can extend across the long or short edge of the rectangle of the standard cell.

In this example, the standard cell architecture reserves one or part of a side of the standard cells to provide an output pin in an epitaxial layer and the opposite side or part to provide one or more input pins in an epitaxial layer. Advantageously, some connections to the front side or back side metal layers can be eliminated by the use of the conductive paths. For example, the CFET drains of such output pins as well as the CFET gates of such input pins avoid any connection to the front side or back side metal layers.

The nodes 1811 and 1821 can be examples of output pins which are not connected to front side or back side metal layers, and the nodes 1831 and 1841 can be examples of input pins which are not connected to front side or back side metal layers.

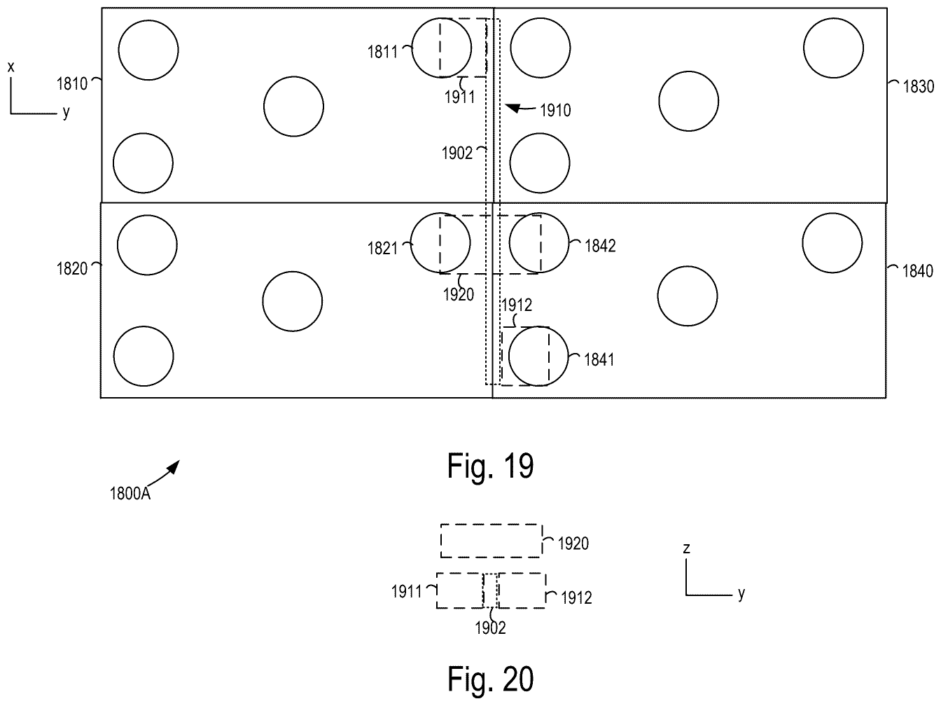

FIG. 19 depicts an example layout of a group 1800A of standard cells corresponding to the group 1800 of FIG. 18, where conductive paths of epitaxial silicon and a channel provide overlapping first and second conductive paths 1910 and 1920, respectively, according to various embodiments. In this example, the nodes 1811 and 1841 are connected by the first conductive path 1910. This path 1910 includes a channel 1902 which extends in the x-direction along a boundary between the cells 1810 and 1830 and a boundary between the cells 1820 and 1840, in one possible approach. Providing the channel on the boundaries ensures that it does not interfere with the placement of circuits within the standard cells. Although, placement of the channel within a standard cell is possible. The channel can comprise a conductive material such as metal or doped silicon. The channel may be non-epitaxial silicon, in one approach.

The channel is connected to the node 1811 by a conductive path 1911 which extends in the y-direction, and to the node 1841 by a conductive path 1912 which extends in the y-direction.

Additionally, the node 1821 is connected to the node 1842 by a conductive path 1920 which goes over or under the channel 1902 to avoid a short circuit with it. This approach allow for multiple connections among adjacent standard cells.

This example can use two separate epitaxial layers, epi1 and epi2, that are available, where shapes in these two layers can be created at separate Z offsets so that they can share the same X, Y coordinates while remaining isolated. The standard cell architecture can also include a channel in which the connection uses shapes in epi1 and epi2 to reach other standard cells facing the same channel. This also allows the creation of one-to-many output-to-input connections. For example, three or more nodes can be connected in two or more standard cells.

In an example implementation, the standard cells 1820, 1840, 1810 and 1830 represent first, second, third and fourth CFET devices, respectively. The conductive path 1920 thus extends from the first CFET device to the second CFET device, and the conductive path 1910 extends from the third CFET device to the second CFET device. The conductive paths 1920, 1911 and 1912 are first, second and third conductive paths or conductive epitaxial silicon materials, respectively.

FIG. 20 depicts an example end view of the conductive paths of epitaxial silicon and the channel of FIG. 19 in the y-z plane, according to various embodiments. In this example, the conductive path 1920 extends over the channel 1902. An insulating material can be provided between the first and second conductive paths 1910 and 1920. The conductive paths can be in two separate (insulated from one another) epitaxial silicon layers at different elevations relative to the substrate. For example, the conductive paths 1911 and 1912 can be in epi1 and the conductive path 1920 can be in epi2, above epi1.

In an example implementation, the first and second conductive epitaxial silicon paths 1911 and 1912 extend in straight lines parallel to one another, and the conductive channel 1902 extends in a straight line perpendicular to the first and second conductive epitaxial silicon paths.

In an example implementation, the standard cells 1810 and 1840 represent first and second CFET devices, respectively, arranged laterally of one another. A first conductive epitaxial silicon path 1911 extends from the first CFET device to the conductive channel 1902, and a second conductive epitaxial silicon path 1912 extends from the second CFET device to the conductive channel. The standard cell 1820 can represent a third CFET device arranged laterally of the first and second CFET devices, where a third conductive epitaxial silicon path 1920 extends from the third CFET device to the second CFET device.

The following discussion involves the positioning of TSVs in a layout of standard cells. The epitaxial silicon paths and TSVs are both examples of interconnects.

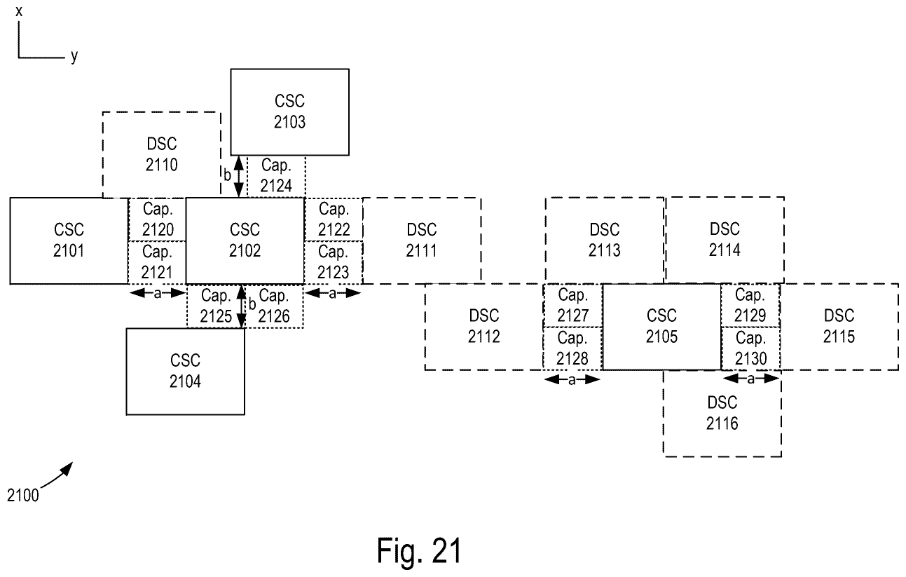

FIG. 21 depicts an example layout of a group 2100 of standard cells including clock standard cells (CSCs), data standard cells (DSCs) and decoupling capacitors (cap.), according to various embodiments. As mentioned, in integrated circuit (IC) design, a standard cell refers to a pre-designed, reusable building block used to construct complex digital circuits. In particular, a standard cell is a small, functional unit of circuitry, such as a logic gate (AND, OR, NOT), flip-flop, or other fundamental logic functions. These cells are designed to be used repeatedly across different parts of an IC. Standard cells simplify the design process by providing a library of pre-designed, well-characterized, and tested circuit components. This helps designers focus on higher-level design issues without having to design each circuit component from scratch.

A standard cell library can be provided which is a collection of standard cells characterized by their logical functions, timing, power consumption, and other electrical properties. Each cell in the library is designed to meet specific performance and layout constraints. The library typically includes various types of logic gates, flip-flops, multiplexers, and other essential building blocks. The cells are designed to be used in a grid-like arrangement, ensuring efficient use of space and ease of routing.

Each standard cell is designed with a fixed height and variable width, which helps in optimizing the layout of the IC. The height is typically fixed to ensure consistent row alignment, while the width can vary depending on the complexity of the cell. The layout of standard cells is optimized for speed, power consumption, and area. Cells are arranged in rows, and the design includes connections for inputs, outputs, and power.

Standard cells are characterized for their timing behavior, including setup and hold times, propagation delays, and drive strength. This information is used for accurate timing analysis and verification. Each cell is also characterized for its power consumption and silicon area. These parameters are used for optimizing the overall power efficiency and area of the IC.

A design flow involves synthesis followed by place and route. In the digital design flow, a high-level design (usually written in Hardware Description Language) is synthesized into a gate-level netlist composed of standard cells. This netlist describes how the logic functions are mapped to standard cells. After synthesis, the place and route process places the standard cells on the silicon and routes the connections between them. The efficiency of this process heavily relies on the design of the standard cells and the library.

Using standard cells accelerates the design process by reducing the need for custom design work. It also enables the reuse of verified components, improving overall reliability. Standard cells allow for the scaling of designs from small to very large integrated circuits while maintaining consistency and performance. Finally, cells are designed to be manufacturable with high yield and reliability, reducing the risk of defects in the final IC.

As mentioned, standard cells can include data or clock cells. A data standard cell (DSC) is in a data path of a circuit. The data path refers, e.g., to the collection of hardware components in a digital circuit that perform operations on data. It can include registers, arithmetic units (like adders or multipliers), multiplexers, buses, and other elements that process and store data. It is responsible for the actual computation and data manipulation within the circuit.

A clock standard cell (DSC) is in a clock path of a circuit. The clock path (or clock distribution path) refers, e.g., to the network of circuitry responsible for delivering the clock signal to all the sequential elements (such as flip-flops) in a circuit. It ensures that all components in the circuit are synchronized and operate in harmony with the clock signal. The clock path can include a clock tree, which is a hierarchical network of buffers and inverters that distribute the clock signal from the clock source to flip-flops and other sequential elements. Clock buffers can be used to amplify and drive the clock signal to various parts of the circuit. Clock gating techniques can be used to disable the clock to certain parts of the circuit when they are not needed, thereby saving power.

The example layout of FIG. 21 includes CSCs 2101-2105 and DSCs 2110-2116. Additionally, the CSCs are separated from other cells by decoupling capacitors. For example, in a common row of cells, CSCs 2101 and 2102 are separated by capacitors 2120 and 2120, and CSC 2102 is separated from DSC 2111 by capacitors 2122 and 2123. CSC 2102 is also separated from CSC 2103 by capacitor 2124, and from CSC 2104 by capacitors 2125 and 2126. In another row, CSC 2105 is separated from DSC 2112 by capacitors 2127 and 2128, and from DSC 2115 by capacitors 2129 and 1230. The separation in the y-direction is “a” and the separation in the x direction is “b.” a>b in some cases.

Standard cells used on clock paths (e.g., inverters, buffers, integrated clock gates) are generally kept distant from each other as depicted by the arrows to avoid a dynamic voltage drop. The gaps are filled with decoupling capacitors which help to mitigate this problem. For high performance designs, this rule is enforced also towards cells on the data path (e.g., registers, circuitry, combinational logic).

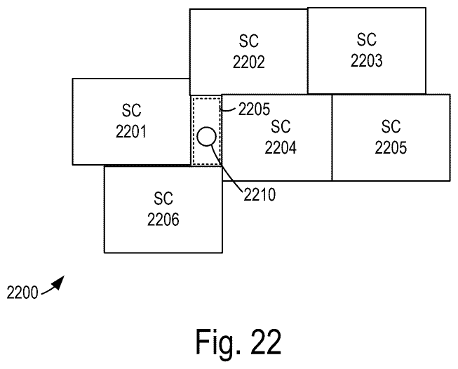

FIG. 22 depicts an example layout of a group 2200 of standard cells, where a through-silicon via (TSV) 2210 is placed in an area 2205 outside the cells, according to various embodiments. The layout includes standard cells (SC) 2201-2206. The area 2205 represented by the dotted line is created between the SCs 2201, 2202, 2204 and 2206. The cells could be data and/or clock cells.

The back side metal layers are typically used for the power distribution network, while the front side metal layers are typically used for signal and clock nets. For cases when a power net needs to connect to the front side or when a signal/clock net needs to connect to the back side, a TSV, e.g., PowerVia can be created. However, the TSV consumes space, which cannot be occupied by a standard cell. For example, a power net may connect to the front side to provide shielding. Another example is that a clock net may need to traverse a large distance, where connecting to the back side metal layer reduces the delay since the back side metal layers tend to be thicker than the front side metal layers and therefore have less resistance.

Some digital place and route tools which are used to insert shielding or to create clock nets and route them use successive refinements in a so-called implementation flow and therefore, can only do an approximate prediction of where the TSVs are effectively needed. They take advantage of incremental placement and routing capabilities to converge to a design-rule clean solution. When additional constraints are added, it can be necessary to restart this process after making more space available for standard cells and their routing.

However, once the TSVs are created, they become additional constraints for the placement of the standard cells. Moreover, large number of TSVs can reduce the maximum utilization that can be achieved for a design with consequent impact on area and wirelength, which consequently can impact dynamic power consumption and performance.

Also, parasitic capacitors are formed between the TSVs and the metal and FETs inside the neighboring standard cells. This can impact the functionality and/or the performance of the standard cell. This forces the designer to consider the presence of TSVs for the boundary conditions used to characterize the standard cells. Since no assumption is made on where the TSV could be inserted, such conditions are necessarily conservative and can sensibly reduce the modelled performance.

The use of integrated TSVs in passive areas of standard cells can alleviate the above-mentioned issues.

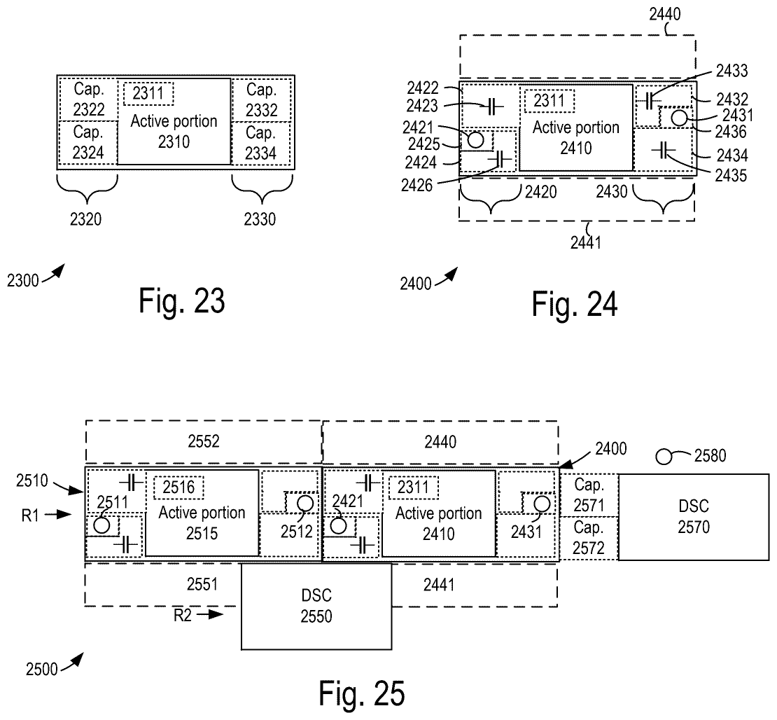

FIG. 23 depicts an example clock standard cell (CSC) which includes an active portion 2310 and passive portions 2320 and 2330, where the passive portion 2320 includes areas 2322 and 2324 for decoupling capacitors (cap.) and the passive portion 2330 includes areas 2332 and 2334 for decoupling capacitors, according to various embodiments. On one end of the cell, the areas 2322 and 2324 can each include one or more capacitors, which help decouple the cell from external effects such as crosstalk and voltage drops. On an opposite end of the cell, the areas 2332 and 2334 can each include one or more capacitors. The active portions can include active components such as described previously, e.g., example active component 2311. The active component can include CFET or other types of devices.

FIG. 24 depicts an example clock standard cell (CSC) 2400 which includes an active portion 2410 and vias 2421 and 2431 located in the passive portions 2420 and 2430, respectively, according to various embodiments. The passive portion 2420 includes an area 2422 for one or more capacitors 2423 but no TSVs, a cutout area 2424 for one or more capacitors 2426 but no TSVs, and an area 2425 for a TSV 2421 but no capacitors. The area 2425 is cutout from a rectangle similar to the area 2324 in FIG. 23. The area 2425 may be rectangular while the cutout area 2424 is L-shaped, for example.

Similarly, the passive portion 2430 includes an area 2434 for one or more capacitors 2435 but no TSVs, a cutout area 2432 for one or more capacitors 2433 but no TSVs, and an area 2436 for a TSV 2431 but no capacitors. The area 2436 may be rectangular while the cutout area 2432 is L-shaped, for example.

In this example, one TSV is provided on each of two opposing short sides of the CSC 2400. Other options are possible. For example, one TSV can be provided in the area 2324 and one in the area 2322, for two TSVs on one side of the cell.

The cell 2400 further includes TSV avoidance areas 2440 and 2441 along the opposing long sides of the cell. These are areas where the TSVs are prohibited. The TSV avoidance areas addresses the possible effects the TSVs have on boundary conditions used to characterize the clock standard cell.

FIG. 25 depicts an example layout 2500 of the clock standard cell 2400 of FIG. 24 with another clock standard cell 2510 and data standard cells 2550 and 2570, according to various embodiments. The layout includes a row R1 with CSCs 2510 and 2400 and DSC 2570. The CSC 2510 includes an active portion 2515 with an active component 2516 and TSVs 2511 and 2512 on opposing sides, similar to the CSC 2400 of FIG. 24. The CSC 2510 also includes TSV avoidance areas 2552 and 2551. A second row R2 includes DSC 2550 which is adjacent to the passive areas of CSCs 2510 and 2400 so there is no need for an additional set of capacitors between the DSC 2550 and the CSCs 2510 and 2400.

Passive areas 2571 and 2572 are used to decouple CSC 2400 from the DSC 2570.

A TSV 2580 is also depicted which is not integrated into the passive area of a cell.

In an example implementation, an apparatus includes a substrate; one or more active components 2311 in a first portion 2410 of the substrate which is allocated to an active area of a standard cell; one or more decoupling capacitors 2423 or 2426 in a second portion 2420 of the substrate which is allocated to a passive area of the standard cell; and one or more through-silicon vias 2421 integrated in the second portion of the substrate.

In one option, the first portion of the substrate is a rectangle; the second portion of the substrate is adjacent to a short side of the rectangle; and third and fourth portions of the substrate 2440 and 2441, respectively, which are adjacent to opposing long sides of the rectangle are allocated as through-silicon via avoidance areas.

The standard cell can be a clock standard cell in a clock path of the substrate. A third portion of the substrate can be allocated to a data standard cell 2570 in a data path of the substrate; and a fourth portion 2571, 2572 of the substrate which is between and adjacent to the second and third portions is allocated to one or more decoupling capacitors.

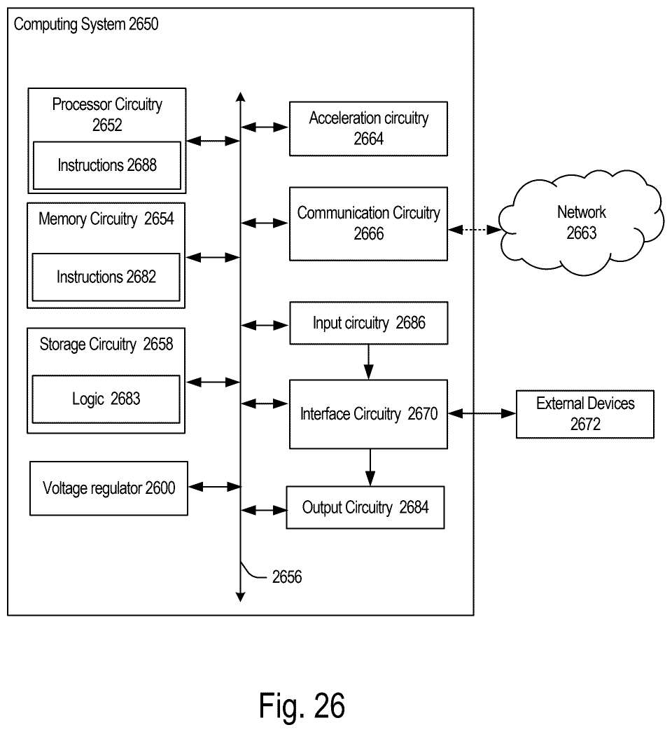

FIG. 26 illustrates an example of components that may be present in a computing system 2650 for implementing the techniques (e.g., operations, processes, methods, and methodologies) described herein.

The computing system 2650 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 2650, or as components otherwise incorporated within a chassis of a larger system. In an example implementation, the CFTE devices, interconnects and TSVs are provided in any of the components 2652, 2654, 2658, 2600, 2664, 2666, 2686, 2670, 2672 or 2684. The CFETs and the conductive epitaxial silicon material can be provided in at least one of an integrated circuit, a System on Chip, a System in Package or a computing device.

The voltage regulator can provide a voltage Vout to one or more of the components of the computing system 2650. The memory circuitry 2654 may store instructions and the processor circuitry 2652 may execute the instructions to perform the functions described herein.

The system 2650 includes processor circuitry in the form of one or more processors 2652. The processor circuitry 2652 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 2652 may include one or more hardware accelerators (e.g., same or similar to acceleration circuitry 2664), which may be microprocessors, programmable processing devices (e.g., FPGA, ASIC, etc.), or the like. The one or more accelerators may include, for example, computer vision and/or deep learning accelerators. In some implementations, the processor circuitry 2652 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 2652 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 2652 may be coupled with or may include memory/storage and may be configured to execute instructions stored in the memory/storage to enable various applications or operating systems to run on the platform 2650. The processors (or cores) 2652 is configured to operate application software to provide a specific service to a user of the platform 2650. In some embodiments, the processor(s) 2652 may be a special-purpose processor(s)/controller(s) configured (or configurable) to operate according to the various embodiments herein.

As examples, the processor(s) 2652 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc. ; or the like. In some implementations, the processor(s) 2652 may be a part of a system on a chip (SoC), System-in-Package (SiP), a multi-chip package (MCP), and/or the like, in which the processor(s) 2652 and other components are formed into a single integrated circuit, or a single package, such as the Edison™ or Galileo™ SoC boards from Intel® Corporation. Other examples of the processor(s) 2652 are mentioned elsewhere in the present disclosure.

The system 2650 may include or be coupled to acceleration circuitry 2664, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 2664 may comprise logic blocks or logic fabric and other interconnected resources that may be programmed (configured) to perform various functions, such as the procedures, methods, functions, etc. of the various embodiments discussed herein. In such implementations, the acceleration circuitry 2664 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 2652 and/or acceleration circuitry 2664 may include hardware elements specifically tailored for machine learning and/or artificial intelligence (AI) functionality. In these implementations, the processor circuitry 2652 and/or acceleration circuitry 2664 may be, or may include, an AI engine chip that can run many different kinds of AI instruction sets once loaded with the appropriate weightings and training code. Additionally or alternatively, the processor circuitry 2652 and/or acceleration circuitry 2664 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPs™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 2652 and/or acceleration circuitry 2664 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin provided by Huawei®, and/or the like. In some hardware-based implementations, individual subsystems of system 2650 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 2650 also includes system memory 2654. Any number of memory devices may be used to provide for a given amount of system memory. As examples, the memory 2654 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 2654 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 2654 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 2658 provides persistent storage of information such as data, applications, operating systems and so forth. In an example, the storage 2658 may be implemented via a solid-state disk drive (SSDD) and/or high-speed electrically erasable memory (commonly referred to as “flash memory”). Other devices that may be used for the storage 2658 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 2654 and/or storage circuitry 2658 may also incorporate three-dimensional (3D) cross-point (XPOINT) memories from Intel® and Micron®.

The memory circuitry 2654 and/or storage circuitry 2658 is/are configured to store computational logic 2683 in the form of software, firmware, microcode, or hardware-level instructions to implement the techniques described herein. The computational logic 2683 may be employed to store working copies and/or permanent copies of programming instructions, or data to create the programming instructions, for the operation of various components of system 2650 (e.g., drivers, libraries, application programming interfaces (APIs), etc.), an operating system of system 2650, one or more applications, and/or for carrying out the embodiments discussed herein. The computational logic 2683 may be stored or loaded into memory circuitry 2654 as instructions 2682, or data to create the instructions 2682, which are then accessed for execution by the processor circuitry 2652 to carry out the functions described herein. The processor circuitry 2652 and/or the acceleration circuitry 2664 accesses the memory circuitry 2654 and/or the storage circuitry 2658 over the interconnect (IX) 2656. The instructions 2682 direct the processor circuitry 2652 to perform a specific sequence or flow of actions, for example, as described with respect to flowchart(s) and block diagram(s) of operations and functionality depicted previously. The various elements may be implemented by assembler instructions supported by processor circuitry 2652 or high-level languages that may be compiled into instructions 2688, or data to create the instructions 2688, to be executed by the processor circuitry 2652. The permanent copy of the programming instructions may be placed into persistent storage devices of storage circuitry 2658 in the factory or in the field through, for example, a distribution medium (not shown), through a communication interface (e.g., from a distribution server (not shown)), over-the-air (OTA), or any combination thereof.

The IX 2656 couples the processor 2652 to communication circuitry 2666 for communications with other devices, such as a remote server (not shown) and the like. The communication circuitry 2666 is a hardware element, or collection of hardware elements, used to communicate over one or more networks 2663 and/or with other devices. In one example, communication circuitry 2666 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 2666 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 2656 also couples the processor 2652 to interface circuitry 2670 that is used to connect system 2650 with one or more external devices 2672. The external devices 2672 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 2650, which are referred to as input circuitry 2686 and output circuitry 2684. The input circuitry 2686 and output circuitry 2684 include one or more user interfaces designed to enable user interaction with the platform 2650 and/or peripheral component interfaces designed to enable peripheral component interaction with the platform 2650. Input circuitry 2686 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 2684 may be included to show information or otherwise convey information, such as sensor readings, actuator position(s), or other like information. Data and/or graphics may be displayed on one or more user interface components of the output circuitry 2684. Output circuitry 2684 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 2650. The output circuitry 2684 may also include speakers and/or other audio emitting devices, printer(s), and/or the like. Additionally or alternatively, sensor(s) may be used as the input circuitry 2684 (e.g., an image capture device, motion capture device, or the like) and one or more actuators may be used as the output device circuitry 2684 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 2650 may communicate over the IX 2656. The IX 2656 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 2656 may be a proprietary bus, for example, used in a SoC based system.

The number, capability, and/or capacity of the elements of system 2650 may vary, depending on whether computing system 2650 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 2650 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Some non-limiting examples of various embodiments are presented below.

Example 1 includes an apparatus, comprising: a first complementary field-effect transistor (CFET) device; a second CFET device arranged laterally of the first CFET device; and a conductive epitaxial silicon material, wherein the conductive epitaxial silicon material provides a conductive path which extends from the first CFET device to the second CFET device.

Example 2 includes the apparatus of Example 1, wherein the conductive path extends within the first CFET device from a drain of an n-channel field-effect transistor (FET) to a drain of a p-channel FET, and the n-channel FET and the p-channel FET are positioned one above the other.

Example 3 includes the apparatus of Example 1 or 2, wherein the conductive epitaxial silicon material provides conductive paths within the first and second CFET devices.

Example 4 includes the apparatus of Example 1 or 2, wherein the conductive path extends from a gate of the first CFET device to a gate of the second CFET device.

Example 5 includes the apparatus of Example 1 or 2, wherein in the first CFET device, the conductive path extends from a gate of an n-channel field-effect transistor (FET) to a gate of a p-channel FET, and the n-channel FET and the p-channel FET are positioned one above the other.

Example 6 includes the apparatus of any one of Examples 1-5, wherein the conductive epitaxial silicon material comprises one or more layers of epitaxial silicon material.

Example 7 includes the apparatus of any one of Examples 1-6, wherein the first CFET device is in an area allocated to a first standard cell and the second CFET device is in an area allocated to a second standard cell, adjacent to the area allocated to the first standard cell.

Example 8 includes the apparatus of any one of Examples 1-7, wherein the conductive epitaxial silicon material is a first conductive epitaxial silicon material, and the apparatus further comprises: a third CFET device; a second conductive epitaxial silicon material; a third conductive epitaxial silicon material; and a conductive channel, wherein: the second conductive epitaxial silicon material extends from the third CFET device to the conductive channel; and the third conductive epitaxial silicon material extends from the second CFET device to the conductive channel.

Example 9 includes the apparatus of Example 8, wherein the conductive channel extends over or under the first conductive epitaxial silicon material.

Example 10 includes the apparatus of Example 8 or 9, wherein: the first CFET device is in an area allocated to a first standard cell; the second CFET device is in an area allocated to a second standard cell, adjacent to the area allocated to the first standard cell; and the third CFET device is in an area allocated to a third standard cell, adjacent to the area allocated to the first standard cell.

Example 11 includes the apparatus of any one of Examples 1-10, wherein the first and second CFETs and the conductive epitaxial silicon material are provided in at least one of an integrated circuit, a System on Chip, a System in Package or a computing device.

Example 12 includes a system, comprising: a substrate; top metal layers above the substrate; a first complementary field-effect transistor (CFET) device in a transistor layer of the substrate; a second CFET device arranged laterally of the first CFET device in the transistor layer of the substrate; and a conductive epitaxial silicon material, wherein the conductive epitaxial silicon material provides a conductive path which extends from the first CFET device to the second CFET device in the transistor layer of the substrate.

Example 13 includes the system of Example 12, wherein the conductive path bypasses the top metal layers.

Example 14 includes the system of Example 12 or 13, wherein: the conductive path extends within the first CFET device from a drain of an n-channel field-effect transistor (FET) to a drain of a p-channel FET; the n-channel FET and the p-channel FET are positioned one above the other; and the conductive path extends within the second CFET device from a drain of an n-channel field-effect transistor (FET) to a drain of a p-channel FET.

Example 15 includes the system of any one of Examples 12-14, wherein: the first CFET device is in an area allocated to a first standard cell; and the second CFET device is in an area allocated to a second standard cell, adjacent to the area allocated to the first standard cell.

Example 16 includes an apparatus, comprising: a substrate; one or more active components in a first portion of the substrate which is allocated to an active area of a standard cell; one or more decoupling capacitors in a second portion of the substrate which is allocated to a passive area of the standard cell; and one or more through-silicon vias integrated in the second portion of the substrate.

Example 17 includes the apparatus of Example 16, wherein the one or more through-silicon vias provide a front side-to-back side feedthrough connection.

Example 18 includes the apparatus of Example 16 or 17, wherein: the first portion of the substrate is a rectangle; the second portion of the substrate is adjacent to a short side of the rectangle; and third and fourth portions of the substrate which are adjacent to opposing long sides of the rectangle are allocated as through-silicon via avoidance areas.

Example 19 includes the apparatus of any one of Examples 16-18, wherein the standard cell is a clock standard cell in a clock path of the substrate.

Example 20 includes the apparatus of any one of Examples 16-19, wherein: the standard cell is a clock standard cell in a clock path of the substrate; a third portion of the substrate is allocated to a data standard cell in a data path of the substrate; and a fourth portion of the substrate which is between and adjacent to the second and third portions is allocated to one or more decoupling capacitors.

Example 21 includes a method, comprising: forming a first complementary field-effect transistor (CFET) device; forming a second CFET device arranged laterally of the first CFET device; and forming a conductive epitaxial silicon material, wherein the conductive epitaxial silicon material provides a conductive path which extends from the first CFET device to the second CFET device.

Example 22 includes the method of Example 21, wherein the conductive epitaxial silicon material provides conductive paths within the first and second CFET devices.

Example 23 includes an apparatus, comprising means to perform the method of Example 21 or 22.

Example 24 includes a machine-readable storage including machine-readable instructions which, when executed, cause a computer to implement the method of Example 21 or 22.

Example 25 includes a computer program comprising instructions which, when executed by a computer, cause the computer to carry out the method of Example 21 or 22.

Example 26 includes a method, comprising: allocating a first portion of a substrate to an active area of a standard cell; forming one or more active components in the first portion of the substrate; allocating a second portion of the substrate to a passive area of the standard cell; forming one or more decoupling capacitors in the second portion of the substrate; and forming one or more through-silicon vias integrated in the second portion of the substrate.

Example 27 includes the method of Example 26, wherein the one or more through-silicon vias provide a front side-to-back side feedthrough connection.

Example 28 includes an apparatus, comprising means to perform the method of Example 26 or 27.

Example 29 includes a machine-readable storage including machine-readable instructions which, when executed, cause a computer to implement the method of Example 26 or 27.

Example 30 includes a computer program comprising instructions which, when executed by a computer, cause the computer to carry out the method of Example 26 or 27.

Example 31 includes a method of manufacturing a circuit, comprising: allocating one or more active components in a first portion of a substrate to an active area of a standard cell; allocating one or more decoupling capacitors in a second portion of the substrate to a passive area of the standard cell; and integrating one or more through-silicon vias in the second portion of the substrate.

Example 32 includes the method of Example 31, wherein the integrating of the one or more through-silicon vias provides a front side-to-back side feedthrough connection.

Example 33 includes the method of Example 31 or 32, wherein the first portion of the substrate is a rectangle, and the second portion of the substrate is adjacent to a short side of the rectangle, the method further comprising: allocating third and fourth portions of the substrate which are adjacent to opposing long sides of the rectangle as through-silicon via avoidance areas.

Example 34 includes the method of any one of Examples 31-33, wherein the standard cell is a clock standard cell in a clock path of the substrate.

Example 35 includes the method of any one of Examples 31-34, wherein the standard cell is a clock standard cell in a clock path of the substrate, the method further comprising: allocating a third portion of the substrate to a data standard cell in a data path of the substrate; and allocating a fourth portion of the substrate which is between and adjacent to the second and third portions to one or more decoupling capacitors.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus, comprising:
a first complementary field-effect transistor (CFET) device;
a second CFET device lateral of the first CFET device; and
a conductive epitaxial silicon material, wherein the conductive epitaxial silicon material provides a conductive path which extends from the first CFET device to the second CFET device.

2. The apparatus of claim 1, wherein the conductive path extends within the first CFET device from a drain of an n-channel field-effect transistor (FET) to a drain of a p-channel FET, and the n-channel FET and the p-channel FET are positioned one above the other.

3. The apparatus of claim 1, wherein the conductive epitaxial silicon material provides conductive paths within the first and second CFET devices.

4. The apparatus of claim 1, wherein the conductive path extends from a gate of the first CFET device to a gate of the second CFET device.

5. The apparatus of claim 1, wherein in the first CFET device, the conductive path extends from a gate of an n-channel field-effect transistor (FET) to a gate of a p-channel FET, and the n-channel FET and the p-channel FET are positioned one above the other.

6. The apparatus of claim 1, wherein the conductive epitaxial silicon material comprises one or more layers of epitaxial silicon material.

7. The apparatus of claim 1, wherein the first CFET device is in an area allocated to a first standard cell and the second CFET device is in an area allocated to a second standard cell, adjacent to the area allocated to the first standard cell.

8. The apparatus of claim 1, wherein the conductive epitaxial silicon material is a first conductive epitaxial silicon material, and the apparatus further comprises:
a third CFET device;
a second conductive epitaxial silicon material;
a third conductive epitaxial silicon material; and
a conductive channel, wherein:
the second conductive epitaxial silicon material extends from the third CFET device to the conductive channel; and
the third conductive epitaxial silicon material extends from the second CFET device to the conductive channel.

9. The apparatus of claim 8, wherein the conductive channel extends over or under the first conductive epitaxial silicon material.

10. The apparatus of claim 8, wherein:
the first CFET device is in an area allocated to a first standard cell;
the second CFET device is in an area allocated to a second standard cell, adjacent to the area allocated to the first standard cell; and
the third CFET device is in an area allocated to a third standard cell, adjacent to the area allocated to the first standard cell.

11. The apparatus of claim 1, wherein the first and second CFETs and the conductive epitaxial silicon material are provided in at least one of an integrated circuit, a System on Chip, a System in Package or a computing device.

12. A system, comprising:
a substrate;
top metal layers above the substrate;
a first complementary field-effect transistor (CFET) device in a transistor layer of the substrate;
a second CFET device lateral of the first CFET device in the transistor layer of the substrate; and
a conductive epitaxial silicon material, wherein the conductive epitaxial silicon material provides a conductive path which extends from the first CFET device to the second CFET device in the transistor layer of the substrate.

13. The system of claim 12, wherein the conductive path bypasses the top metal layers.

14. The system of claim 12, wherein:
the conductive path extends within the first CFET device from a drain of an n-channel field-effect transistor (FET) to a drain of a p-channel FET;
the n-channel FET and the p-channel FET are positioned one above the other; and
the conductive path extends within the second CFET device from a drain of an n-channel field-effect transistor (FET) to a drain of a p-channel FET.

15. The system of claim 12, wherein:
the first CFET device is in an area allocated to a first standard cell; and
the second CFET device is in an area allocated to a second standard cell, adjacent to the area allocated to the first standard cell.

16. A method of manufacturing a circuit, comprising:
allocating one or more active components in a first portion of a substrate to an active area of a standard cell;
allocating one or more decoupling capacitors in a second portion of the substrate to a passive area of the standard cell; and
integrating one or more through-silicon vias in the second portion of the substrate.

17. The method of claim 16, wherein the integrating of the one or more through-silicon vias provides a front side-to-back side feedthrough connection.

18. The method of claim 16, wherein the first portion of the substrate is a rectangle, and the second portion of the substrate is adjacent to a short side of the rectangle, the method further comprising:
allocating third and fourth portions of the substrate which are adjacent to opposing long sides of the rectangle as through-silicon via avoidance areas.

19. The method of claim 16, wherein the standard cell is a clock standard cell in a clock path of the substrate.

20. The method of claim 16, wherein the standard cell is a clock standard cell in a clock path of the substrate, the method further comprising:
allocating a third portion of the substrate to a data standard cell in a data path of the substrate; and
allocating a fourth portion of the substrate which is between and adjacent to the second and third portions to one or more decoupling capacitors.
